(19) United States
(12) Patent Application Publication
(10) Pub. No.: US 2015/0159412 A1
(43) Pub. Date: Jun. 11, 2015

(54) SELF-LOCKING INJECT/EJECT LATCH

(71) Applicant: Alcatel-Lucent, Paris (FR)

(72) Inventors: Reinhold J. Seitz, Hilpoltstein (DE); Diethard Stiller, Egloffstein (DE)

(73) Assignee: ALCATEL-LUCENT, PARIS (FR)

(21) Appl. No.: 14/101,738

(22) Filed: Dec. 10, 2013

(51) Int. Cl. E05C 3/12; E05B 65/00; H05K 7/14

(52) U.S. Cl. CPC E05C 3/12; H05K 7/1402; E05B 65/00

(57) ABSTRACT

A latch that can be used as a mechanical aid for insertion/extraction of a circuit pack into/from a slot in an equipment cabinet. In an example embodiment, a handle of the latch contains a spring-biased locking lever that automatically locks the latch in the closed position when the pawl of the latch engages the keeper. Some embodiments may include an integrated micro-switch that enables a graceful shutdown of the circuit pack, e.g., to avoid an extraction without a proper power-down. At least some embodiments of the latch may also have one or more of the following beneficial characteristics: (i) a relatively large and/or variable leverage ratio; (ii) a relatively small footprint on the faceplate of the circuit pack; (iii) a fully symmetric design with or without the integrated micro-switch; and (iv) enhanced electromagnetic compatibility with the use of an electrically conducting latch base and/or gasket.

### BACKGROUND

1. Field

The present disclosure relates to latches and levers and, more specifically but not exclusively, to inject/eject latches that may be adapted for use to secure and release circuit boards, circuit cards, opto-electronic modules, and the like in connector slots, sub-racks, racks, trays, cabinets, and other enclosures.

2. Description of the Related Art

This section introduces aspects that may help facilitate a better understanding of the invention(s) disclosed herein. Accordingly, the statements of this section are to be read in this light and are not to be understood as admissions about what is in the prior art or what is not in the prior art.

The term “latch” generally refers to a mechanical fastener configured to join together two or more mating objects or surfaces while allowing for frequent or occasional reversible separation of said mating objects or surfaces. A latch is typically movably attached to a first mating object and is configured to reversibly engage/disengage another piece of hardware (referred to as a keeper or strike) fixedly attached to a second mating object. Depending on the intended application, latches may range in complexity from relatively simple one-piece hardware elements to fairly complex multi-part mechanical devices.

### SUMMARY OF SOME SPECIFIC EMBODIMENTS

Disclosed herein are various embodiments of a self-locking inject/eject latch that can be used, e.g., as a mechanical aid for insertion/extraction of a corresponding circuit pack into/from a respective slot in a sub-rack or an equipment cabinet. The latch can also securely hold the circuit pack in the inserted position, e.g., to maintain the corresponding electrical and/or optical connections even when the circuit pack or the equipment cabinet is jarred or jostled. In an example embodiment, a handle of the latch contains a spring-biased locking lever configured to automatically lock the latch in the closed position when the pawl of the latching member engages the corresponding keeper. Some embodiments of the latch may include an integrated micro-switch that enables a graceful shutdown of the circuit pack, e.g., to avoid an extraction without a proper power-down. At least some embodiments of the latch may also have one or more of the following beneficial characteristics: (i) a relatively large and/or variable leverage ratio; (ii) a relatively small footprint on the faceplate of the circuit pack; (iii) a fully symmetric design with or without the integrated micro-switch; and (iv) enhanced electromagnetic compatibility with the use of an electrically conducting latch base and/or gasket.

According to one embodiment, provided is an apparatus comprising a first latch, wherein the first latch comprises: a latch base; a latching member connected to the latch base and configured to rotate with respect to the latch base about a first rotation axis; and a locking lever connected to the latching member and configured to rotate with respect to the latching member about a second rotation axis. In a closed state of the first latch, a hook of the locking lever is configured to interlock with a hook of the latch base to lock the first latch.

According to another embodiment, provided is a latch comprising: a latch base; a latching member connected to the latch base and configured to rotate with respect to the latch base about a first rotation axis; and a locking lever connected to the latching member and configured to rotate with respect to the latching member about a second rotation axis. In a closed state of the latch, a hook of the locking lever is configured to interlock with a hook of the latch base to lock the latch.

### BRIEF DESCRIPTION OF THE DRAWINGS

Other aspects, features, and benefits of various embodiments of the invention will become more fully apparent, by way of example, from the following detailed description and the accompanying drawings, in which:

FIGS. 1A-1B show three-dimensional perspective views of a latch according to an embodiment of the disclosure;

FIG. 2 shows a three-dimensional perspective view of various constituent parts of the latch shown in FIG. 1 according to an embodiment of the disclosure;

FIGS. 3A-3D illustrate the faceplate of a circuit pack having two latches of FIG. 1 attached thereto according to an embodiment of the disclosure;

FIGS. 4A-4B illustrate an electromagnetic-compatibility (EMC) gasket that can be used in the latch shown in FIG. 1 according to an embodiment of the disclosure;

FIGS. 5A-5B show closed and open states of the latch shown in FIG. 1 according to an embodiment of the disclosure;

FIG. 6 shows a three-dimensional perspective view of a latching member that can be used in the latch shown in FIG. 1 according to an alternative embodiment of the disclosure;

FIG. 7 shows a three-dimensional perspective view of a latching member that can be used in the latch shown in FIG. 1 according to another alternative embodiment of the disclosure;

FIGS. 8A-8D show several representative states of the latch of FIG. 1 according to an embodiment of the disclosure; and

FIG. 9 shows a cross-sectional side view of an equipment cabinet according to an embodiment of the disclosure.

### DETAILED DESCRIPTION

An electronic and/or optical module held in a larger enclosure, such as an equipment rack or cabinet, often needs to be outfitted with a mechanical aid that enables relatively easy insertion of said module into the enclosure and the subsequent relatively easy extraction of said module there from. Said mechanical aid may also be designed to securely hold the module in the inserted position, e.g., to maintain the corresponding electrical and/or optical connections even when the module or the enclosure is jarred or jostled.

Various embodiments of an inject/eject latch disclosed herein can be used as the above-described mechanical aid. More specifically, an example inject/eject latch of the disclosure can be mounted on a faceplate or front panel of the corresponding module, circuit pack, or drawer such that the handle of the latch can be pivoted to cause the pawl or jaw of the latch to engage or disengage the keeper. The pawl or jaw is shaped such that (i) pivoting the handle in one direction generates an insertion force that pushes the module, circuit pack, or drawer into the enclosure and (ii) pivoting the handle in the opposite direction generates an extraction force that pulls the module, circuit pack, or drawer out of the enclosure. When the pawl and keeper are mutually engaged, the module, circuit pack, or drawer is securely fastened to the enclosure. In some embodiments, the keeper may comprise a cross-member attached to the frame of the enclosure.

In addition to the above-indicated inject/eject and fastening functions, some latch embodiments disclosed herein may have one or more of the following features/characteristics: (i) a relatively large leverage ratio; (ii) a relatively small footprint on the faceplate or front panel of the corresponding module, circuit pack, or drawer; (iii) enhanced electromagnetic-compatibility (EMC) characteristics; and (iv) an integrated micro-switch configured to be triggered upon the latch opening and closing. The relatively large leverage ratio may address a need for the generation of relatively large insertion and extraction forces that may be necessary in the process of handling a circuit pack with a relatively high pin count at the backplane. Such circuit packs become more and more prevalent, e.g., in contemporary communication systems. The relatively small footprint of the latch on the faceplate or front panel may address a need for making most of the surface area on the faceplate or front panel available for the elements of an input/output (I/O) interface, which tends to have a relatively high I/O port density in contemporary communication systems. The enhanced EMC characteristics may address a need for improved electromagnetic shielding properties, e.g., to support substantially interference-free operation of various electronic circuits configured to operate at a relatively high bit rate or clock frequency. The integrated micro-switch may address a need for a graceful shutdown of various digital circuits, e.g., when an attempt at the extraction of the corresponding circuit pack occurs without or prior to its proper power-down.

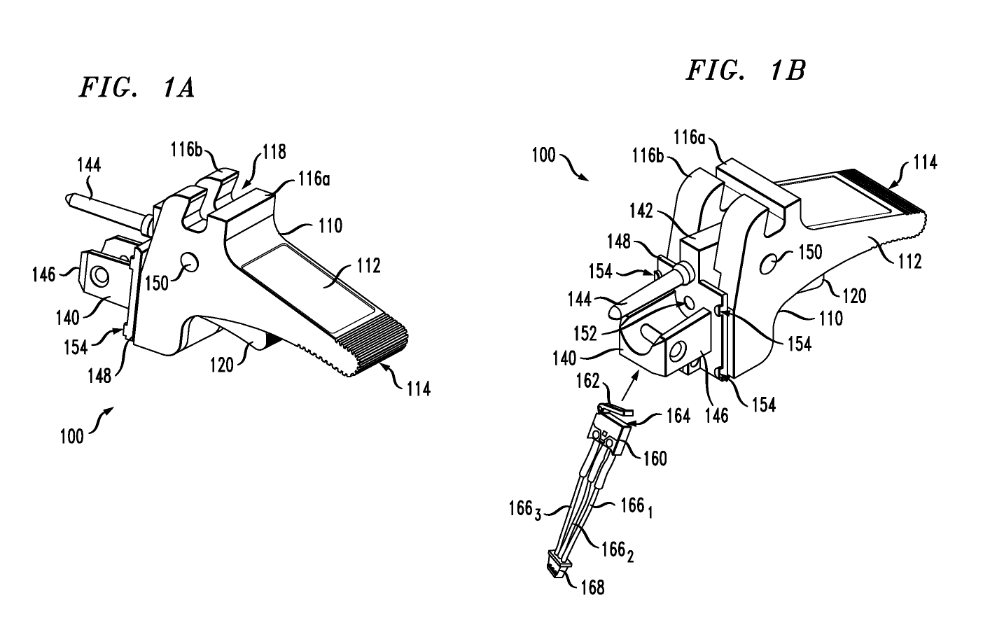

FIGS. 1A-1B show three-dimensional perspective views of a latch 100 according to an embodiment of the disclosure. More specifically, FIG. 1A shows a view of latch 100 substantially from a handle side of the latch. FIG. 1B shows a view of latch 100 substantially from a base side of the latch. FIG. 1B also shows an optional micro-switch 160 that can be inserted into a base 140 of latch 100 as indicated in the figure. In one embodiment, micro-switch 160 is the model P7-0-46720 micro-switch that is commercially available from Southco, Inc., headquartered in Concordville, Pa.

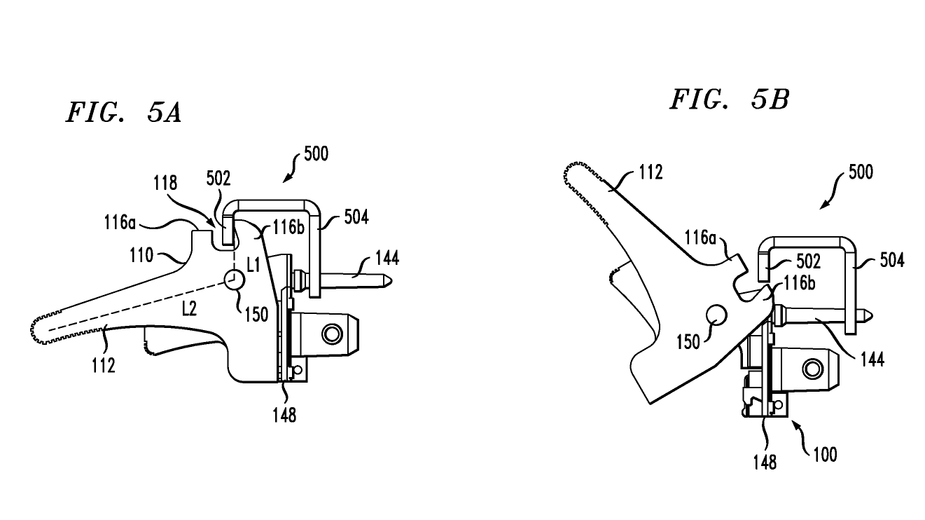

Latch 100 comprises a latching member 110 that is rotatably coupled to base 140 using a pivot pin 150. Latching member 110 has a handle 112 that can be used to pivot the latching member about the rotation axis defined by pivot pin 150. Said pivoting can be used to change the relative orientation of latching member 110 and base 140, e.g., as indicated in FIGS. 5A-5B. The distal end of handle 112 has a textured surface 114 whose contoured profile serves to reduce the occurrence of slippage of the operator's hand in the process of gripping the handle and turning it around pivot pin 150. In the embodiment shown in FIGS. 1A-1B, textured surface 114 has a plurality of relatively shallow grooves that are approximately perpendicular to the longer side of handle 112. In alternative embodiments, other suitable contoured profiles can similarly be used to form textured surface 114.

Latching member 110 further has a pawl 116 having an outer lip 116a and a bifurcated inner lip 116b. A slot 118 between outer lip 116a and inner lip 116b is shaped to accommodate a corresponding keeper, e.g., as indicated in FIG. 5A. The gap between the two portions of bifurcated inner lip 116b enables proper coupling between latching member 110 and base 140 by accepting a holed protrusion 142 of the latter in the manner that enables proper insertion of pivot pin 150 into the latching member and base when the hole in the protrusion is aligned with the corresponding holes in the latching member.

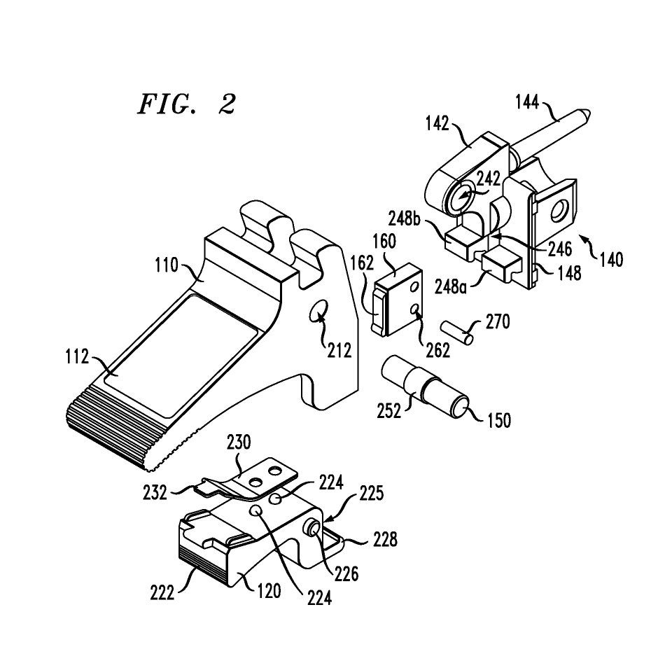

Handle 112 of latching member 110 is partially hollow and is shaped to accommodate a lever 120, which is only partially visible in the views shown in FIGS. 1A-1B. Lever 120 is configured to lock latch 100, e.g., when pawl 116 engages a corresponding keeper, which may include a cross-member of a sub-rack (not shown in FIG. 1). Lever 120 may also be used to activate optional micro-switch 160. A more-detailed description of lever 120 is given below, e.g., in reference to FIG. 2.

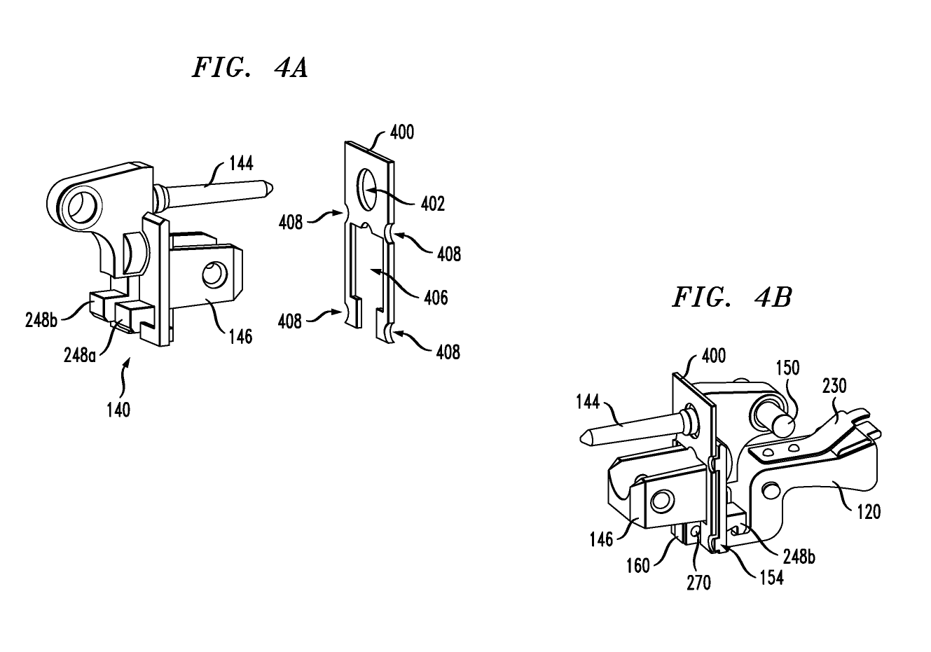

Latch base 140 includes an alignment pin 144 that can be used to guide the module, circuit pack, or drawer to which latch 100 is attached into a proper alignment position within the corresponding slot of the larger enclosure. For example, in embodiments having an EMC gasket (see FIG. 4), lateral forces might be generated during the insertion or extraction process that can move the faceplate to which latch 100 is attached away from its intended position. Alignment pin 144 may therefore be useful to mitigate an undesired effect of said lateral forces. In some embodiments, alignment pin 144 can be detachable from base 140, e.g., by means of a threaded stub that can be screwed into a matching threaded hole in protrusion 142 (neither of which is explicitly shown in FIGS. 1A-1B). In some embodiments, alignment pin 144 can be absent altogether.

Base 140 further includes a holed anchoring member 146 that can be used, e.g., to anchor a circuit board in the corresponding module, circuit pack, or drawer. For example, both alignment pin 144 and anchoring member 146 can be inserted into respective cutouts in the faceplate of the corresponding module, circuit pack, or drawer such that (i) a foot portion 148 of base 140 is substantially flush with the outer surface of the faceplate and (ii) the alignment pin and anchoring member protrude, through the cutouts in the faceplate, into the interior portion of the module, circuit pack, or drawer. The corresponding circuit board can be attached to anchoring member 146, e.g., using a screw inserted into the threaded hole therein.

In an example embodiment, foot portion 148 is a substantially flat plate configured to cover up most of the cutouts in the faceplate. When base 140 is made of an electrically conducting material (e.g., metal), this configuration of foot portion 148 serves to effectively block off the external electromagnetic radiation that would otherwise penetrate through the cutouts into the interior portion of the module, circuit pack, or drawer and possibly interfere with the operation of the electronic circuits therein. Also, the electromagnetic radiation generated in the interior portion of the module, circuit pack, or drawer may be blocked from escaping to the exterior. The electromagnetic shielding provided by foot 148 may therefore be used to improve and/or enhance the EMC characteristics of the corresponding module or drawer.

Base 140 also has a slotted opening into which micro-switch 160 can be inserted, e.g., as indicated in FIG. 1B. In the view shown in FIG. 1B, the slotted opening is oriented vertically and located just beneath anchoring member 146, which partially obscures the view of the opening in that figure. When micro-switch 160 is inserted into the slotted opening and secured therein, e.g., using a spiral pin or a dowel pin, a switch actuator 162 is placed in proximity to a side surface of lever 120 (also see FIG. 2). When latch 100 is in a closed state, said side surface of lever 120 pushes on switch actuator 162 to cause it to be pressed against a proximate edge 164 of micro-switch 160. When latch 100 is opened and the side surface of lever 120 no longer pushes on switch actuator 162, the latter swings out, thereby changing the state of micro-switch 160.

In an example embodiment, micro-switch 160 has three terminals, each connected to a corresponding one of wires 166₁-166₃. The terminal connected to wire 166₃ is a common terminal. The terminal connected to wire 166₁ is open when switch actuator 162 is pressed against edge 164, and is closed when the switch actuator is released. In contrast, the terminal connected to wire 166₂ is open when switch actuator 162 is released, and is closed when the switch actuator is pressed against edge 164. Wires 166₁-166₃ can be electrically connected to the circuit board attached to anchoring member 146, e.g., using a connector 168.

FIG. 2 shows a three-dimensional perspective view of various constituent parts of latch 100 (FIG. 1) according to an embodiment of the disclosure. In particular, FIG. 2 illustrates in more detail the structure of lever 120, base 140, and pivot pin 150 (see FIG. 1). Also explicitly shown in FIG. 2 are a flat spring 230 and a spiral pin 270, which are not visible in the views shown in FIGS. 1A-1B. From the provided description, one of ordinary skill in the art will understand how to put together the latch parts shown in FIG. 2 to arrive at the assembled structure of latch 100 shown in FIG. 1.

Flat spring 230 has a bent shape, e.g., illustrated in FIG. 2, and is configured to apply a spring force to lever 120 when a distal end 222 of the lever is pressed into handle 112 of latching member 110. Flat spring 230 has a pair of holes configured to accept (e.g., using a press fit) a matching pair of short stubs 224 located on an upper surface of lever 120. Flat spring 230 further has a tongue portion 232 configured to be in contact with an inner surface of handle 112 to enable the flat spring to respond to a change in the relative position of handle 112 and distal end 222 of lever 120.

Lever 120 has a pair of cylindrical side extensions 226, only one of which is visible in the view shown in FIG. 2. Cylindrical side extensions 226 are configured to snap into a matching pair of depressions on the inner surface of latching member 110 (not explicitly shown in FIG. 2). When snapped in place, cylindrical side extensions 226 define a rotation axis for lever 120. As a result, lever 120 can be pivoted about said rotation axis with respect to latching member 110, e.g., by squeezing together distal end 222 of the lever and handle 112.

Lever 120 further has a hook 228 configured to interlock with a matching bifurcated hook 248 attached to foot portion 148 of base 140. The two portions of bifurcated hook 248 are labeled in FIG. 2 as 248a and 248b. Hooks 228 and 248 and flat spring 230 can be used to make latch 100 a self-locking latch, for example, as follows. In some embodiments, hooks 228 and 248 may have slanted front facets, in which case latch 100 may be locked by simply rotating latching member 110 about the rotation axis defined by pivot pin 150 while applying sufficient torque to handle 112 to cause the slanted facets to slide with respect to one another, thereby causing lever 120 to rotate about the rotation axis defined by cylindrical side extensions 226 until hook 228 clears the front portion of hook 248 and the spring force generated by flat spring 230 causes hooks 228 and 248 to snap into the interlocked position.

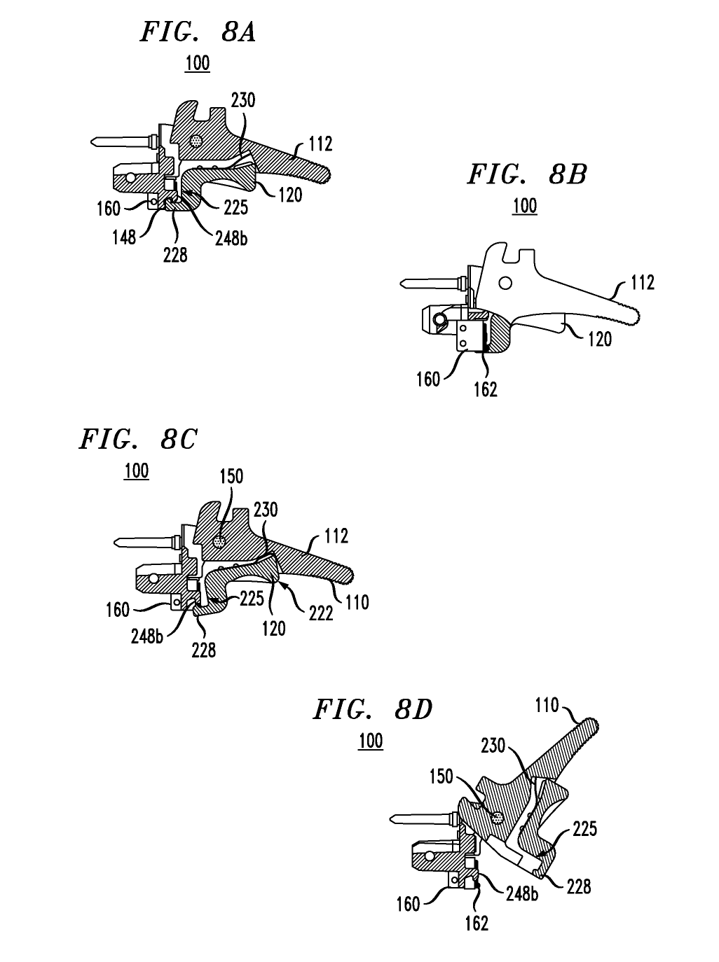

In an alternative embodiment, hooks 228 and 248 can be interlocked, e.g., using the following sequence of steps: (i) squeezing together distal end 222 of lever 120 and handle 112 of latching member 110; (ii) rotating latching member 110 about the rotation axis defined by pivot pin 150 to an end position where hooks 228 and 248 are placed next to each other but not yet interlocked; and (iii) releasing the squeezing pressure applied to distal end 222 and handle 112 to enable hooks 228 and 248 to interlock due to the force and motion generated by flat spring 230. From the interlocked state, hooks 228 and 248 can be unlocked, e.g., using the following sequence of steps: (i) squeezing together distal end 222 of lever 120 and handle 112 of latching member 110 to offset hooks 228 and 248 from one another by opening up a gap between them; (ii) rotating latching member 110 about the rotation axis defined by pivot pin 150 to separate hooks 228 and 248; and (iii) releasing the squeezing pressure applied to distal end 222 and handle 112. Representative states of latch 100 that can be produced during the locking/unlocking of the latch are further described below in reference to FIGS. 8A-8D.

A side surface 225 of lever 120 is substantially orthogonal to the base of hook 228 and configured to press switch actuator 162 of micro-switch 160 against the proximate edge of the switch when hooks 228 and 248 are interlocked. Switch actuator 162 is released and swings out when hooks 228 and 248 are unlocked and latch 110 is in an open state.

Pivot pin 150 is substantially cylindrical in shape, but has a slightly thicker middle portion 252. The diameter of middle portion 252 is selected such that pivot pin 150 can be press-fitted into a hole 242 in protrusion 142 of base 140. The thinner end portions of pivot pin 150 have a diameter that enables pivot pin 150 to rotate relatively easily inside holes 212 in latching member 110 when the latching member is pivoted with respect to base 140.

Micro-switch 160 can be inserted, through the gap between the two portions of bifurcated hook 248, into a slotted opening 246 in foot portion 148 of base 140. Spiral pin 270 is then inserted into a hole 262 in the body of micro-switch 160 and the matching holes in base 140 (not explicitly shown in FIG. 2; see FIG. 4B) to fix the micro-switch in slotted opening 246. Spiral pin 270 has an uncompressed body diameter that is larger than the diameter of the receiving holes, and a chamfer on either one or both ends of the spiral pin facilitates starting the spiral pin into the holes. The spring action of spiral pin 270 allows it to compress as it assumes the diameter of the holes. The radial force exerted by spiral pin 270 against the walls of the receiving holes retains it in the holes, thereby fastening micro-switch 160 to base 140 in a self-retaining manner.

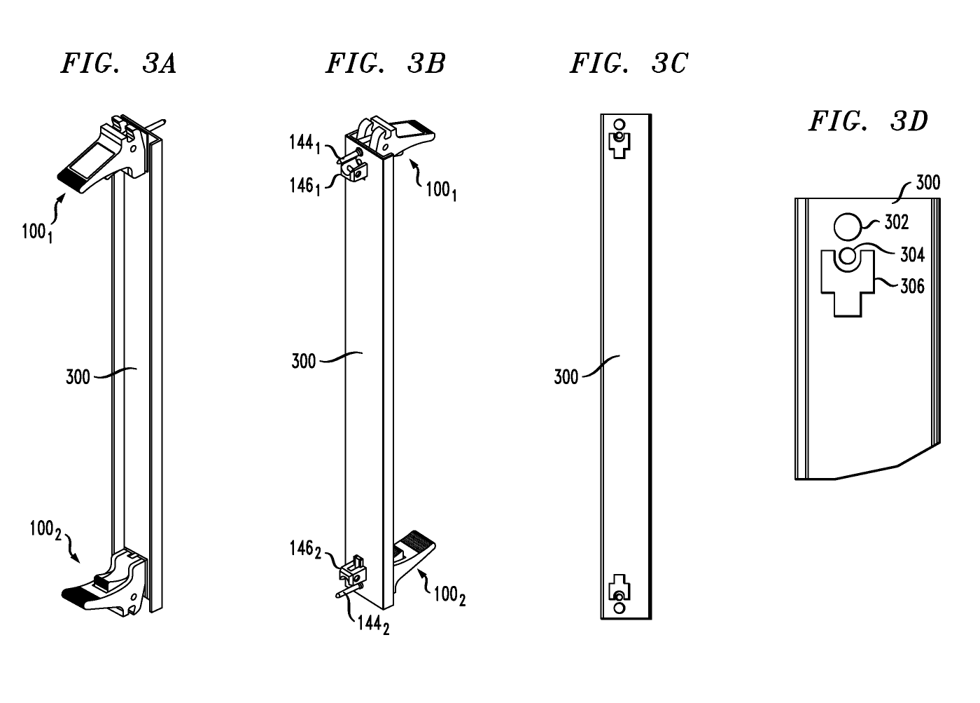

FIGS. 3A-3D illustrate a faceplate 300 of a circuit pack having two latches 100 attached thereto according to an embodiment of the disclosure. More specifically, FIG. 3A shows a three-dimensional perspective view of faceplate 300 substantially from an outer side of the corresponding circuit pack (not fully shown in FIG. 3A for clarity). FIG. 3B shows a three-dimensional perspective view of faceplate 300 substantially from an inner side of the corresponding circuit pack (not fully shown in FIG. 3B for clarity). FIG. 3C shows a top view of faceplate 300 prior to the attachment of latches 100. FIG. 3D shows an enlarged view of an end portion of faceplate 300 corresponding to the view shown in FIG. 3C.

Referring to FIGS. 3A-3B, the two latches 100 (labeled 100₁ and 100₂, respectively) are nominally identical to one another, e.g., with each being a separate instance (copy) of latch 100 shown in FIG. 1. The use of the same latch model at the upper and lower ends of faceplate 300 is enabled by the fact that the structure of latch 100 (in the assembled form) is symmetric with respect to a plane of symmetry that passes through the center axis of alignment pin 144 parallel to the longer side of handle 112 (e.g., see FIG. 1). As such, latch 100 is a mirror image of itself with respect to that plane of symmetry. Note that the plane of symmetry is preserved with or without micro-switch 160 being present in latch 100. This characteristic of latch 100 may distinguish this latch from functionally comparable prior-art latches, which are inherently asymmetric. Examples of such asymmetric latches are disclosed, e.g., in U.S. Pat. No. 7,397,674, which is incorporated herein by reference in its entirety. Disadvantageously, a latch having an asymmetric structure requires two different models of the latch to be attached to the opposite ends of the faceplate, with the two models being essentially mirror images of one another.

The view presented in FIG. 3B illustrates how alignment pin 144 and anchoring member 146 of latch 100 may protrude through the respective cutouts in faceplate 300. FIGS. 3C and 3D show the cutout shapes in more detail. In an example embodiment, the cutouts in faceplate 300 include round holes 302 and 304 and an opening 306 (e.g., see FIG. 3D). Round hole 302 has a diameter that enables insertion of alignment pin 144 into this hole, e.g., as indicated in FIG. 3B. Round hole 304 has a position that aligns it with a blind threaded hole 152 (see FIG. 1B) in foot portion 148 of base 140. In an example embodiment, hole 304 is used to attach latch 100 to faceplate 300, e.g., using a screw that is fed through hole 304 into threaded hole 152 and tightened therein. Opening 306 has a shape that enables insertion of anchoring member 146 and a back portion of micro-switch 160 into this opening, e.g., as indicated in FIG. 3B.

After latch 100 is attached to faceplate 300, foot portion 148 may substantially fully cover round hole 304 and opening 306. The foot portion of protrusion 142 (see FIG. 1B) may similarly substantially fully cover round hole 302. When base 140 is made of an electrically conducting material, foot portion 148 and foot portion of protrusion 142 inhibit penetration of external electromagnetic radiation through the cutouts in faceplate 300. This shielding action of latch 100 with respect to holes 302 and 304 and opening 306 may advantageously enable the circuit pack having faceplate 300 to have improved EMC characteristics compared to those achievable with functionally comparable prior-art latches.

FIGS. 4A-4B illustrate an EMC gasket 400 that can be used in latch 100 according to an embodiment of the disclosure. More specifically, FIG. 4A shows EMC gasket 400 together with base 140 to illustrate the mutually compatible shapes of these two parts. FIG. 4B shows a three-dimensional perspective view of a partially assembled latch 100, with EMC gasket 400 incorporated into its structure and with latching member 110 being taken out.

In an example embodiment, EMC gasket 400 is made of an electrically conducting material, such as fabric over foam, a metal, or metallic alloy. As such, EMC gasket 400 can be used to improve EMC characteristics of latch 100 even when base 140 is not made of an electrically conducting material. In some embodiments, both EMC gasket 400 and base 140 can be made of electrically conducting materials.

EMC gasket 400 has a round hole 402 that has a diameter that enables insertion of alignment pin 144 into this hole, e.g., as indicated in FIG. 4B. EMC gasket 400 further has an opening 406 of a shape that enables insertion of anchoring member 146 and a back portion of micro-switch 160 into this opening, e.g., as further indicated in FIG. 4B. EMC gasket 400 may also have four optional side cutouts 408 configured to accommodate optional stand-offs 154 extending from foot portion 148 of base 140, e.g., as indicated in FIG. 4B, for better fixation of the EMC gasket in latch 100. Stand-offs 154 are also configured to control the compression of EMC gasket 400. Note that stand-offs 154 are also shown, e.g., in FIG. 1B. In some embodiments, both side cutouts 408 and stand-offs 154 may be absent. When latch 100 is attached to faceplate 300, e.g., as shown in FIGS. 3A-3B, EMC gasket 400 contacts the outer surface of the faceplate and covers a significant portion of hole 302 and opening 306 (see FIG. 3D) to inhibit penetration of external and internal electromagnetic radiation through these faceplate cutouts, thereby improving the shielding characteristics of the faceplate.

FIGS. 5A-5B show closed and open states of latch 100 according to an embodiment of the disclosure. More specifically, FIG. 5A shows a side view of latch 100 with pawl 116 being engaged with a keeper 500. FIG. 5B shows a side view of latch 100 with pawl 116 being disengaged from keeper 500 and partially extracted there from.

In the embodiment shown in FIGS. 5A-5B, keeper 500 comprises a bracket having a relatively short front wall 502 and a relatively tall back wall 504. Back wall 504 has a hole in it, into which alignment pin 144 can be inserted, e.g., as indicated in FIGS. 5A-5B, to guide the circuit pack to which latch 100 is attached during the circuit-pack injection into or ejection from the corresponding larger enclosure. In the closed state of latch 100, front wall 502 is inserted into slot 118 in pawl 116, e.g., as indicated in FIG. 5A, and handle 112 is oriented approximately orthogonally (e.g., within +/−15 degrees with respect to the normal) to foot portion 148 in base 140.

To transition from the closed state shown in FIG. 5A to the open state shown in FIG. 5B, handle 112 is rotated about pivot pin 150 by approximately 60 degrees in the clockwise direction. During this rotation, the pawl's outer lip 116a is pressed against the outer surface of front wall 502, thereby generating an extraction force. To transition from the open state shown in FIG. 5B back to the closed state shown in FIG. 5A, handle 112 is rotated about pivot pin 150 in the counterclockwise direction. During this rotation, the pawl's inner lip 116b is pressed against the inner surface of front wall 502, thereby generating an insertion force.

The magnitude of the extraction and insertion forces generated by the rotation of handle 112 depends on the leverage ratio, R, of latching member 110. More specifically, leverage ratio R can be defined as the ratio of the length (L₂) of handle 112 and the length (L₁) of pawl 116, i.e., R=L₂/L₁. Both lengths L₁ and L₂ are indicated in FIG. 5A by the respective dashed lines. In the above-described embodiments of latch 100, leverage ratio R is approximately 3.6. This leverage ratio enables latches 100₁ and 100₂ (FIGS. 3A-3B) to generate and withstand without breaking (i) an insertion force of at least up to about 800 N per circuit pack or 400 N per individual latch 100 and (ii) an extraction force of up to about 300 N per circuit pack or 150 N per individual latch 100.

FIG. 6 shows a three-dimensional perspective view of a latching member 600 that can be used instead of latching member 110 in latch 100 according to an alternative embodiment of the disclosure. Latching member 600 is generally similar to latching member 110 (FIG. 1), except that a handle 612 of latching member 600 has a movable retractable extension 620. Retractable extension 620 comprises side rails 624₁-624₂ and cylindrical rods 626₁-626₂ joined together by a connecting bar 622, e.g., as indicated in FIG. 6. Handle 612 has side grooves 614, only one of which is visible in the view shown in FIG. 6. Grooves 614 are configured to accommodate side rails 624₁-624₂ to guide the letter when retractable extension 620 is moved with respect to handle 612. Cylindrical rods 626₁-626₂ are configured to fit into the corresponding holes (not visible in the view of shown in FIG. 6) in handle 612 and have a sufficiently large diameter to withstand and transfer to the handle the torque that may be applied to latching member 600 during insertion/extraction of the corresponding circuit pack. In the fully extended state, retractable extension 620 enables the corresponding latch to have a leverage ratio R of approximately 7.5. When retractable extension 620 is fully retracted, the corresponding latch has a leverage ratio R of approximately 3. One of ordinary skill in the art will appreciate that intermediate positions of retractable extension 620 can provide any leverage-ratio value from the range between 3 and 7.5.

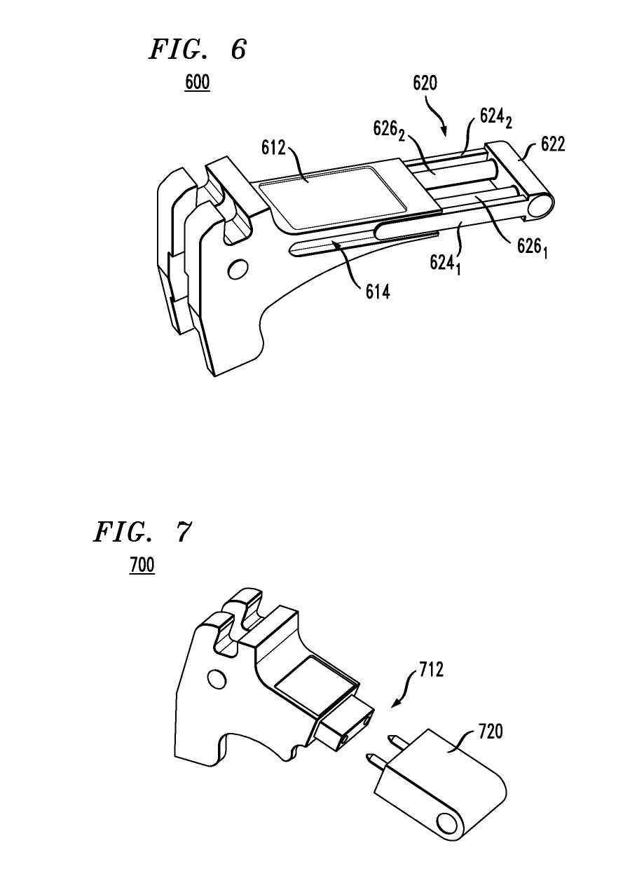

FIG. 7 shows a three-dimensional perspective view of a latching member 700 that can be used instead of latching member 110 in latch 100 according to another alternative embodiment of the disclosure. Latching member 700 is generally similar to latching member 110 (FIG. 1), except that a handle 712 of latching member 700 has a detachable end portion 720. In some embodiments, end portion 720 can be an external tool, meaning that a single end portion 720 can be used with multiple latching members 700. In an example embodiment, end portion 720 can be detached from latching member 700 after the corresponding latch has been locked in place, e.g., as shown in FIG. 5A. The detachment of end portion 720 may provide one or both of the following benefits: (i) reduce the probability of the latch unlocking when (the shortened) handle 712 is accidentally pushed or bumped and (ii) reduce the possible interference of the latch with the cable connections at the faceplate of the corresponding circuit pack. End portion 720 can be reattached to latching member 700, e.g., when the corresponding latch needs to be unlocked, e.g., as shown in FIG. 5B.

FIGS. 8A-8D show several representative states of latch 100 that may be encountered during the latch locking/unlocking according to an embodiment of the disclosure. FIGS. 8A, 8C, and 8D show cross-sectional side views of latch 100, wherein the cross-section plane passes through portion 248b of hook 248 (also see FIGS. 2 and 4). FIG. 8B shows a side view of latch 100 with a partial cross-section around micro-switch 160.

FIGS. 8A-8B show the same state of latch 100, which is similar to the state shown in FIG. 5A. In this state, latch 100 is closed, and handle 112 is approximately orthogonal to foot portion 148 or faceplate 300. Lever 120 is locked due to hooks 228 and 248 being in the interlocked position, which can be clearly seen in FIG. 8A. Actuator 162 of micro-switch 160 is pressed against the body of the micro-switch by side surface 225 of lever 120, thereby causing the micro-switch to be in a first state (e.g., the state in which the terminal connected to wire 166₁ is open, see FIG. 1B).

In the state shown in FIG. 8C, latch 100 is still closed, but lever 120 is now unlocked. The unlocking has been achieved by rotating lever 120 with respect to latching member 110, e.g., by pressing distal end 222 of the lever into handle 112. The rotation compresses flat spring 230 (as can be seen by comparing FIGS. 8A and 8C) and causes hooks 228 and 248 to become vertically offset with respect to one another as indicated in FIG. 8C. Actuator 162 of micro-switch 160 is no longer pressed against the body of the micro-switch by side surface 225 of lever 120, thereby causing the actuator to spring out and the micro-switch to transition from the first state to a second state (e.g., the state in which the terminal connected to wire 166₁ is closed, see FIG. 1B).

In the state shown in FIG. 8D, latch 100 is open. The opening has been achieved by rotating latching member 110 about pivot pin 150 as can be seen by comparing FIGS. 8C and 8D. Lever 120 is unlocked and will remain unlocked even if distal end 222 of the lever is released and flat spring 230 is allowed to decompress as indicated in FIG. 8D because a relatively large distance now separates hooks 228 and 248 from one another. Actuator 162 of micro-switch 160 remains released, thereby causing the micro-switch to remain in the second state, e.g., the same state as in FIG. 8C.

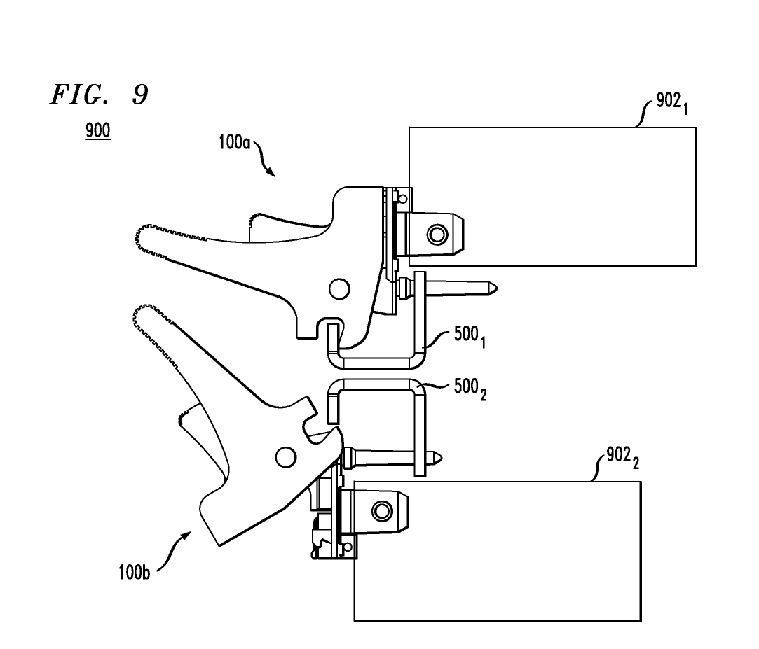

FIG. 9 shows a cross-sectional side view of an equipment cabinet 900 according to an embodiment of the disclosure. Equipment cabinet 900 has two vertically stacked card slots, with the upper slot being provided with a first keeper 500₁, and the lower slot being provided with a second keeper 500₂, both of which keepers are similar to keeper 500 of FIG. 5. Inserted into the upper slot is a first circuit pack having a circuit board 902₁ whose lower side is attached to a first latch 100a, which is a copy of latch 100 (FIG. 1). Inserted into the lower slot is a second circuit pack having a circuit board 902₂ whose upper side is attached to a second latch 100b, which is also a copy of latch 100 (FIG. 1).

To achieve a relatively high density and/or count of circuit packs in equipment cabinet 900, keepers 500₁ and 500₂ are placed relatively close to each other, e.g., to substantially abut each other in equipment cabinet 900 as indicated in FIG. 9. As a consequence, latches 100a and 100b are also placed relatively close to each other, and special care may be required in the process of inserting/extracting the corresponding circuit packs into/from equipment cabinet 900. For example, latch 100a is shown in FIG. 9 as being in a closed and locked state, whereas latch 100b is in an opened and unlocked state. Inspection of FIG. 9 for the relative handle positions in latches 100a and 100b reveals that the spacing between the latches might be too tight for both of the latches to be opened simultaneously. More specifically, if one attempts to open latch 100a in the position shown in FIG. 9, then the handle of latch 100b might interfere with the rotation of the handle in latch 100a, thereby preventing the latter latch from transitioning into a fully opened and unlocked state similar to that of the former latch. Therefore, the operator of equipment cabinet 900 might have to handle one circuit pack at a time to avoid such interference. However, the benefit of achieving a relatively high density and/or count of circuit packs in equipment cabinet 900 might still outweigh the minor inconvenience of handling the adjacent, vertically stacked circuit packs one at a time.

Various embodiments of the latches, faceplates, and circuit packs disclosed herein may include features that make these devices at least partially compatible with the following standards: (i) CompactPCI; (ii) Advanced Telecom Computing Architecture, ATCA; (iii) IEC 60917; and (iv) IEC 60297, all of which are incorporated herein by reference in their entirety.

Various embodiments of the latches disclosed herein may provide one or more of the following benefits:
(i) a symmetric latch design with or without an integrated micro-switch that enables the use of the same latch model at the top and the bottom of a faceplate;
(ii) a self-locking feature (e.g., implemented using a lever that rotates but does not shift) that enables activation of the integrated micro-switch when only an attempt is made to unlock the latch and prior to any actual movement of the circuit pack within the corresponding slot in the enclosure;
(iii) enhanced EMC shielding with an electrically conducting latch base and/or with the use of an EMC gasket;
(iv) relatively small cutouts in the faceplate;
(v) relatively large leverage ratio R for the generation of relatively large insertion/extraction forces;
(vi) flexible material selection (wherein the latch can be implemented, e.g., as a die cast part) to make the latch more robust and suitable for higher insertion/extraction forces;
(vii) variable leverage ratio R, e.g., implemented using a telescopic extension of the handle or an add-on tool;
(viii) with the latch handle being oriented approximately orthogonally to the faceplate, the latch footprint on the faceplate can be relatively small while the leverage ratio R can still be relatively large and/or adjustable;
(ix) variable latch placement on the faceplate, e.g., to accommodate various card positions, which may depend on the printed-wire-board thickness and the selected card slot in a sub-rack; and
(x) relatively easy assembly of the constituent parts of the latch (for example, the pivot of lever 120 is designed as a snap-in axis).

According to an example embodiment disclosed above in reference to FIGS. 1-9, provided is an apparatus (e.g., 900, FIG. 9) comprising a first latch (e.g., 100, FIG. 1). The first latch comprises: a latch base (e.g., 140, FIGS. 1-2); a latching member (e.g., 110, FIG. 1; 600, FIG. 6; 700, FIG. 7) connected to the latch base and configured to rotate with respect to the latch base about a first rotation axis (e.g., designed with a snap-in feature for easy assembly); and a locking lever (e.g., 120, FIGS. 1-2) connected to the latching member and configured to rotate with respect to the latching member about a second rotation axis. In a closed state of the first latch (e.g., shown in FIGS. 8A-8B), a hook (e.g., 228, FIG. 2) of the locking lever is configured to interlock with a hook (e.g., 248, FIG. 2) of the latch base to lock the first latch.

In some embodiments of the above apparatus, the first rotation axis is defined by a pivot pin (e.g., 150, FIG. 2) inserted into a hole (e.g., 242, FIG. 2) in the latch base and a matching hole (e.g., 212, FIG. 2) in the latching member; and the second rotation axis is defined by a pair of cylindrical extensions (e.g., 226, FIG. 2) on opposite sides of the locking lever.

In some embodiments of any of the above apparatus, the second rotation axis is parallel to but not collinear with the first rotation axis.

In some embodiments of any of the above apparatus, a portion of the locking lever is inserted into a cavity in the latching member (e.g., having a snap-in feature to accommodate the second rotation axis for easy assembly); and the locking lever is configured to rotate with respect to the latch base about the first rotation axis together with the latching member.

In some embodiments of any of the above apparatus, the hook of the locking lever has a slanted front facet configured to slide with respect to the hook of the latch base when said hooks are in direct physical contact with one another and the latching member is rotated about the first rotation axis in the locking direction (e.g., hooks of the locking lever snap into hooks of the latch base during closing of the latch without a special manual effort; only for the latch opening, the hooks need to be disengaged by pressing the locking lever down, which also triggers the micro-switch).

In some embodiments of any of the above apparatus, the first latch further comprises a spring (e.g., 230, FIGS. 2 and 8) positioned between the latching member and the locking lever and configured to apply a return torque to the locking lever when a distal end (e.g., 222, FIG. 2) of the locking lever is pressed into a handle (e.g., 112, FIGS. 1-2) of the latching member. In an alternative embodiment, the spring may also be an integral part of the locking lever, e.g., in the case of using plastic injection-molded parts. In another alternative embodiment, the spring may also be an integral part of the latching member or be attached to the latching member.

In some embodiments of any of the above apparatus, the first latch further comprises a micro-switch (e.g., 160, FIGS. 1, 2, 8) inserted into a slotted opening (e.g., 246, FIG. 2) in the latch base. The presence of the micro-switch does not change the overall symmetry of the latch.

In some embodiments of any of the above apparatus, the micro-switch is secured in the slotted opening by a spiral pin (e.g., 270, FIG. 2) or a dowel pin inserted into a hole (e.g., 262, FIG. 2) in the micro-switch and a matching hole in the latch base (e.g., as shown in FIG. 4B).

In some embodiments of any of the above apparatus, the locking lever is configured to press a switch actuator (e.g., 162, FIG. 2, 8) against a body of the micro-switch when the hook of the locking lever and the hook of the latch base are interlocked.

In some embodiments of any of the above apparatus, the locking lever is further configured to cause the switch actuator to change a state of the micro-switch when a distal end (e.g., 222, FIG. 2) of the locking lever is pressed into a handle (e.g., 112, FIGS. 1-2) of the latching member with the latching member still being in a position corresponding to the closed state of the first latch (e.g., as shown in FIG. 8C).

In some embodiments of any of the above apparatus, the locking lever is further configured to cause the switch actuator to be released when the first latch transitions from the closed state to an open state (e.g., through the sequence of states shown in FIGS. 8B to 8D).

In some embodiments of any of the above apparatus, a handle (e.g., 612, FIG. 6) of the latching member has a movable retractable extension (e.g., 620, FIG. 6) configured to cause a leverage ratio (e.g., R) of the latching member to be variable.

In some embodiments of any of the above apparatus, the leverage ratio is variable within a range between approximately 3 (e.g., 2.8 to 3.2) and approximately 7.3 (e.g., 7.0 to 7.6).

In some embodiments of any of the above apparatus, a handle (e.g., 712, FIG. 7) of the latching member has a detachable portion (e.g., 720, FIG. 7).

In some embodiments of any of the above apparatus, the first latch is symmetric with respect to a plane of symmetry passing therethrough.

In some embodiments of any of the above apparatus, the apparatus further comprises: a faceplate (e.g., 300, FIG. 3), wherein the first latch (e.g., 100₁, FIG. 3) is attached to the faceplate; and a circuit board (e.g., 902, FIG. 9) attached to an anchoring member (e.g., 146, FIG. 1) of the latch base, which is inserted into an opening (e.g., 306, FIG. 3D) in the faceplate, wherein the opening is an internal opening surrounded on all sides, without breaks, by portions of the faceplate.

In some embodiments of any of the above apparatus, the apparatus further comprises a second latch (e.g., 100₂, FIG. 3) attached to the faceplate at an opposite end thereof with respect to the first latch, wherein the second latch is nominally identical to the first latch but is mounted on the faceplate with a different orientation (e.g., upside down).

In some embodiments of any of the above apparatus, the apparatus further comprises an electrically conducting gasket (e.g., 400, FIG. 4) inserted between the latch base and the faceplate and configured to at least partially cover the opening.

In some embodiments of any of the above apparatus, the latch base includes an alignment pin (e.g., 144, FIG. 1) inserted into a hole (e.g., 302, FIG. 3D) in the faceplate; and the electrically conducting gasket is further configured to at least partially cover said hole.

In some embodiments of any of the above apparatus, the apparatus further comprises a keeper (e.g., 500, FIG. 5), wherein the latching member comprises a pawl (e.g., 116, FIGS. 1, 5) configured to engage the keeper in the closed state of the first latch (e.g., as shown in FIG. 5A).

In some embodiments of any of the above apparatus, the pawl comprises a first lip (e.g., 116a, FIG. 1) and a bifurcated second lip (e.g., 116b, FIG. 1), said lips being separated by a slot (e.g., 118, FIG. 1) configured to accommodate the keeper (e.g., as shown in FIG. 5A); and the latching member is configured to rotate about the first rotation axis such that (i) a rotation of the latching member in a first direction causes the first lip to push on the accommodated keeper to generate an extraction force for the circuit board and (ii) a rotation of the latching member in an opposite second direction causes the bifurcated second lip to push on the accommodated keeper to generate an insertion force for the circuit board.

In some embodiments of any of the above apparatus, in the closed state of the first latch, a handle (e.g., 112, FIGS. 1-2) of the latching member is approximately (e.g., within +/−15 degrees) orthogonal to the faceplate.

According to another example embodiment disclosed above in reference to FIGS. 1-9, provided is a latch (e.g., 100, FIG. 1) comprising: a latch base (e.g., 140, FIGS. 1-2); a latching member (e.g., 110, FIG. 1; 600, FIG. 6; 700, FIG. 7) connected to the latch base and configured to rotate with respect to the latch base about a first rotation axis; and a locking lever (e.g., 120, FIGS. 1-2) connected to the latching member and configured to rotate with respect to the latching member about a second rotation axis. In a closed state of the latch (e.g., shown in FIGS. 8A-8B), a hook (e.g., 228, FIG. 2) of the locking lever is configured to interlock with a hook (e.g., 248, FIG. 2) of the latch base to lock the latch.

While this invention has been described with reference to illustrative embodiments, this description is not intended to be construed in a limiting sense. Various modifications of the described embodiments, as well as other embodiments of the invention, which are apparent to persons skilled in the art to which the invention pertains are deemed to lie within the principle and scope of the invention as expressed in the following claims.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention(s) may be made by those skilled in the art without departing from the scope of the invention as expressed in the following claims.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Throughout the detailed description, the drawings, which are not all to scale, are illustrative only and are used in order to explain, rather than limit the invention(s). The use of terms such as height, length, width, top, bottom, upper, lower is strictly to facilitate the description of the invention(s) and is not intended to limit the invention(s) to a specific orientation. For example, height does not imply only a vertical rise limitation, but is used to identify one of the three dimensions of a three dimensional structure as shown in the figures. Such “height” would be vertical in one orientation of the latch but would be horizontal in another orientation of the latch, and so on.

Also for purposes of this description, the terms “couple,” “coupling,” “coupled,” “connect,” “connecting,” or “connected” refer to any manner known in the art or later developed in which energy or force is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term compatible means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

The description and drawings merely illustrate the principles of the invention. It will thus be appreciated that those of ordinary skill in the art will be able to devise various arrangements that, although not explicitly described or shown herein, embody the principles of the invention and are included within its spirit and scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

What is claimed is:

1. An apparatus comprising a first latch, wherein the first latch comprises:
a latch base;
a latching member connected to the latch base and configured to rotate with respect to the latch base about a first rotation axis; and
a locking lever connected to the latching member and configured to rotate with respect to the latching member about a second rotation axis; and
wherein, in a closed state of the first latch, a hook of the locking lever is configured to interlock with a hook of the latch base to lock the first latch.

2. The apparatus of claim 1, wherein:
the first rotation axis is defined by a pivot pin inserted into a hole in the latch base and a matching hole in the latching member; and
the second rotation axis is defined by a pair of cylindrical extensions on opposite sides of the locking lever.

3. The apparatus of claim 1, wherein the second rotation axis is parallel to but not collinear with the first rotation axis.

4. The apparatus of claim 1, wherein:
a portion of the locking lever is inserted into a cavity in the latching member; and
the locking lever is configured to rotate with respect to the latch base about the first rotation axis together with the latching member.

5. The apparatus of claim 1, wherein the hook of the locking lever has a slanted front facet configured to slide with respect to the hook of the latch base when the latching member is rotated about the first rotation axis to transition to the closed state.

6. The apparatus of claim 1, wherein the first latch further comprises a spring positioned between the latching member and the locking lever and configured to apply a return torque to the locking lever when a distal end of the locking lever is pressed into a handle of the latching member.

7. The apparatus of claim 1, wherein the first latch further comprises a micro-switch inserted into a slotted opening in the latch base.

8. The apparatus of claim 7, wherein the locking lever is configured to press a switch actuator against a body of the micro-switch when the hook of the locking lever and the hook of the latch base are interlocked.

9. The apparatus of claim 8, wherein the locking lever is further configured to cause the switch actuator to change a state of the micro-switch when a distal end of the locking lever is pressed into a handle of the latching member with the latching member still being in a position corresponding to the closed state of the first latch.

10. The apparatus of claim 8, wherein the locking lever is further configured to cause the switch actuator to be released when the first latch transitions from the closed state to an open state.

11. The apparatus of claim 1, wherein a handle of the latching member has a movable retractable extension configured to cause a leverage ratio of the latching member to be variable.

12. The apparatus of claim 11, wherein the leverage ratio is variable within a range between approximately 3.0 and approximately 7.3.

13. The apparatus of claim 1, wherein a handle of the latching member has a detachable portion.

14. The apparatus of claim 1, wherein the first latch is symmetric with respect to a plane of symmetry passing therethrough.

15. The apparatus of claim 1, further comprising:
a faceplate, wherein the first latch is attached to the faceplate; and
a circuit board attached to an anchoring member of the latch base, which is inserted into an opening in the faceplate, wherein the opening is an internal opening surrounded on all sides, without breaks, by portions of the faceplate.

16. The apparatus of claim 15, further comprising a second latch attached to the faceplate at an opposite end thereof with respect to the first latch, wherein the second latch is nominally identical to the first latch.

17. The apparatus of claim 15, further comprising a gasket inserted between the latch base and the faceplate and configured to at least partially cover the opening, wherein:
the gasket comprises a material that is an electrical conductor;
the latch base includes an alignment pin inserted into a hole in the faceplate; and
the gasket is further configured to at least partially cover said hole.

18. The apparatus of claim 15, further comprising a keeper, wherein the latching member comprises a pawl configured to engage the keeper in the closed state of the first latch, wherein:
the pawl comprises a first lip and a bifurcated second lip, said lips being separated by a slot configured to accommodate the keeper; and
the latching member is configured to rotate about the first rotation axis such that (i) a rotation of the latching member in a first direction causes the first lip to push on the accommodated keeper to generate an extraction force for the circuit board and (ii) a rotation of the latching member in an opposite second direction causes the bifurcated second lip to push on the accommodated keeper to generate an insertion force for the circuit board.

19. The apparatus of claim 15, wherein, in the closed state of the first latch, a handle of the latching member is approximately orthogonal to the faceplate.

20. A latch comprising:
a latch base;
a latching member connected to the latch base and configured to rotate with respect to the latch base about a first rotation axis; and
a locking lever connected to the latching member and configured to rotate with respect to the latching member about a second rotation axis; and
wherein, in a closed state of the latch, a hook of the locking lever is configured to interlock with a hook of the latch base to lock the latch.
